(19) United States
(12) Patent Application Publication
(10) Pub. No.: US 2008/0211781 A1
(43) Pub. Date: Sep. 4, 2008

(54) Photoelectric transducer capable of detecting a finger resting on it, and display panel having the same

(75) Inventor: Takumi Yamamoto, Hino-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Casio Computer Co.,Ltd., Tokyo (JP)

(21) Appl. No.: 12/012,977

(22) Filed: Feb. 6, 2008

(30) Foreign Application Priority Data
Feb. 8, 2007 (JP) 2007-029310

(51) Int. Cl. G06F 3/042; H01L 33/00

(52) U.S. Cl. 345/173; 257/80; 257/E33.001

(57) ABSTRACT

A photoelectric transducer according to this invention includes a photoelectric-transducer element array which has a first and a second regions in which a first and a second photoelectric transducer elements having a photoelectric transducer part are arranged, respectively, and a light-emitting member which is arranged below the photoelectric-transducer element array. Above the photoelectric-transducer element array, a mount layer is arranged, on which an object is to rest to reflect the light emitted from the light-emitting member to the first and the second photoelectric transducer elements. A first and a second light-shielding layers are provided between the light-emitting members and the photoelectric transducer part of the first and the second photoelectric transducer elements, respectively. The second light-shielding layer has a larger area than the first light-shielding layer. The light emitted from the light-emitting member therefore passes through the first region in a larger amount than through the second region.

### CROSS-REFERENCE TO RELATED APPLICATIONS

This application is based upon and claims the benefit of priority from prior Japanese Patent Application No. 2007-029310, filed Feb. 8, 2007, the entire contents of which are incorporated herein by reference.

### BACKGROUND OF THE INVENTION

1. Field of the Invention

The present invention relates to a photoelectric transducer. More particularly, the invention relates to a photoelectric transducer that can detect an object such as a finger resting on it and also to a display panel that has the photoelectric transducer.

2. Description of the Related Art

A device is known, which includes a photoelectric transducer element provided on an insulating substrate, particularly on a transparent substrate. Jpn. Pat. Appln. KOKAI Publication No. 6-236980 discloses a device comprising a plurality of thin-film-transistor (hereinafter referred to as TFT) photoelectric transducer elements (hereinafter referred to as TFT photoelectric transducer elements) which are arranged, one adjacent to another, and each of which has a photoelectric transducer part made of amorphous silicon (hereinafter referred to as a-Si).

FIG. 8 shows the photoelectric characteristic of an a-Si TFT photoelectric transducer element of the ordinary type. This characteristic has been determined by measuring the drain-source current Ids [A], using the luminance of illumination light as parameter under conditions such that channel width/length (W/L) ratio=180000/9 μm, source voltage Vs=0V and drain voltage Vd=10V.

As seen from FIG. 8, the drain-source current Ids increases as the luminance of the illumination light increases. In particular, when the luminance of the illumination light increases, the drain source current Ids prominently increases in a reverse bias region where the gate-source voltage has a negative value (Vgs<0). Usually, the characteristic observed in this reverse bias region is utilized so that the a-Si TFT photoelectric transducer element may be used as a photoelectric transducer element that detects the luminance of the illumination light as a change in the drain-source current Ids.

FIG. 9 is a sectional view showing a structure that a photoelectric transducer having such TFT photoelectric transducer elements 10 may have.

Each TFT photoelectric transducer element 10 includes a gate electrode 14, transparent insulating films 16 and 17, a photoelectric transducer part 18, a source electrode 20, and a drain electrode 21. The gate electrode 14 is formed on a transparent TFT substrate 12. The transparent insulating film 16 is formed on the gate electrode 14. The photoelectric transducer part 18 is made of a-Si, formed on the insulating film 16 and opposed to the gate electrode 14. The source electrode 20 and drain electrode 21 are formed on the photoelectric transducer part 18. The transparent insulating film 17 covers the upper surface of the TFT photoelectric transducer elements 10. A gap 23 is provided on the transparent insulating film 17 by a seal member (not shown) or a gap member (not shown) and thus a transparent countersubstrate 22 is spaced apart by a prescribed distance from the transparent insulating film 17. A photoelectric transducer is thus fabricated.

The prescribed distance is determined from the space between any adjacent TFT photoelectric transducer elements 10 and the refractive indices of the other components of the photoelectric transducer. That is, the distance is determined so that the light 26 applied from a backlight 24 arranged at the back of the TFT substrate 12 to the countersubstrate 22 through the space between the adjacent TFT photoelectric transducer elements 10 may be reflected by an object, such as a finger 28 resting on the countersubstrate 22 and the reflected light 30 can then be reliably converted to an electrical signal by the photoelectric transducer part 18 made of a-Si.

In this photoelectric transducer, the photoelectric transducer part 18 converts the reflected light 40, i.e., light 26 reflected by the finger 28 (more precisely, the ridges defining the fingerprint, which are not shown), to an electrical signal. The finger print is recognized from this electrical signal.

With the conventional photoelectric transducer described above, however, the reflected light 30 cannot be distinguished from the light applied form outside (particularly, sunlight) that has luminance equal to or higher than that of the reflected light 30. If the finger 28 does not rest on the countersubstrate 22, the extraneous light is applied to the photoelectric transducer part 18 of the TFT photoelectric transducer element 10, exactly in the same way as the reflected light 30 (i.e., light 26 reflected by the finger 28). Inevitably, the reflected light 30, i.e., signal light, cannot be distinguished from the extraneous light such as sunlight. In view of this, the conventional photoelectric transducer cannot be used in an apparatus, such as a touch panel, which generates control signal upon detecting object (e.g., finger) resting on it.

### BRIEF SUMMARY OF THE INVENTION

The present invention has been made in consideration of the foregoing. An object of the invention is to provide a photoelectric transducer that can detect an object, if any, resting on it even if the extraneous light applied to it has luminance equal to or higher than the light emitted from the backlight. Another object of this invention is to provide a display panel that has such a photoelectric transducer.

A photoelectric transducer according to this invention includes a photoelectric-transducer element array which has a first region (A1) in which a first photoelectric transducer element (100-1) having a photoelectric transducer part (18) is arranged and a second region (A2) in which a second photoelectric transducer element (100-2) having a photoelectric transducer part (18) is arranged, and a light-emitting member (24) which is arranged below the photoelectric-transducer element array and which emits light (26) to the photoelectric-transducer element array. Above the photoelectric-transducer element array, a mount layer (22) is arranged, on which an object (28) is to rest to reflect the light (26) emitted from the light-emitting member (24) toward the photoelectric-transducer element array, to the first photoelectric transducer element (100-1) and the second photoelectric transducer element (100-2). A first light-shielding layer (14) is provided between the light-emitting member (24) and the photoelectric transducer part (18) of the first photoelectric transducer element (100-1) and a second light-shielding layer (15) is provided between the light-emitting member (24) and the photoelectric transducer part (18) of the second photoelectric transducer element (100-2) and having a larger area than the first light-shielding layer (14). The light (26) emitted from the light-emitting member (24) toward the photoelectric-transducer element array therefore passes through the first region (A1) in a larger amount than through the second region (A2).

A display panel according to the present invention has a display region (118) and a touch-panel region (122) and includes: a TFT substrate (128); a light-emitting member (24) which is arranged on a lower surface of the TFT substrate (128); and a countersubstrate (22) which is spaced apart from and opposed to an upper surface of the TFT substrate (128). Between the countersubstrate (22) and that part of the TFT substrate (128) which is aligned with the display region (118), there are provided: pixel electrodes; switching elements which are connected to the pixel electrodes; and a liquid crystal which covers the switching elements. Between the countersubstrate (22) and that part of the TFT substrate (128) which is aligned with the touch-panel region (122), there are provided: a photoelectric-transducer element array which has a first region (A1) in which a first photoelectric transducer element (100-1) having a photoelectric transducer part (18) is arranged and a second region (A2) in which a second photoelectric transducer element (100-2) having a photoelectric transducer part (18) is arranged; a light-emitting member (24) which is arranged below the photoelectric-transducer element array and which emits light (26) to the photoelectric-transducer element array; a mount layer (22) which is arranged above photoelectric-transducer element array and on which an object (28) is to rest to reflect the light (26) emitted from the light-emitting member (24) toward the photoelectric-transducer element array, to the first photoelectric transducer element (100-1) and the second photoelectric transducer element (100-2); a first light-shielding layer (14) which is provided between the light-emitting member (24) and the photoelectric transducer part (18) of the first photoelectric transducer element (100-1); and a second light-shielding layer (15) which is provided between the light-emitting member (24) and the photoelectric transducer part (18) of the second photoelectric transducer element (100-2) and having a larger area than the first light-shielding layer (14).

According to the present invention, only the first photoelectric transducer element performs photoelectric conversion on signal light such as light reflected by the object, and both the first photoelectric transducer element and the second photoelectric transducer element perform photoelectric conversion on extraneous light such as sunlight. The photoelectric transducer element array can therefore generate an output which changes in accordance with the type of light applied to it. Hence, the present invention can provide a photoelectric transducer that can distinguish signal light, such as the reflected light, can therefore be distinguished from the extraneous light, such as sunlight.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1A is a sectional view showing a photoelectric transducer according to a first embodiment of the present invention;

FIG. 1B is a plan view of the photoelectric transducer shown in FIG. 1A;

FIG. 2A is a sectional view explaining how light travels in the photoelectric transducer shown in FIG. 1A when a finger touches the countersubstrate of the photoelectric transducer;

FIG. 2B is a sectional view explaining how intense extraneous light, if applied, travels in the photoelectric transducer shown in FIG. 1A;

FIG. 2C is a table showing the various operating modes of the photoelectric transducer according to the first embodiment;

FIG. 3 is a circuit diagram of the detection circuit that determines whether sensor TFTs have converted light to an electrical signal;

FIG. 4 is a diagram showing how the sensor TFTs are electrically connected in the photoelectric transducer according to the first embodiment;

FIG. 5 is a diagram showing a TFT-LCD panel that incorporates a plurality of photoelectric transducers according to the first embodiment;

FIG. 6 is a sectional view showing the configuration of a photoelectric transducer according to a second embodiment of the present invention;

FIG. 7A is a diagram showing an arrangement of gate electrodes of a photoelectric transducer according to a third embodiment of the invention, which is configured as a touch sensor that has five first sensor TFTs and four second TFT sensors;

FIG. 7B is a diagram representing the circuit configuration of the photoelectric transducer shown in FIG. 7A;

FIG. 7C is an equivalent circuit diagram showing the photoelectric transducer shown in FIG. 7A;

FIG. 8 is a graph representing the photoelectric characteristic of a conventional TFT photoelectric transducer; and

FIG. 9 is a magnified sectional view showing the configuration of the conventional TFT photoelectric transducer.

### DETAILED DESCRIPTION OF THE INVENTION

The best modes for carrying out this invention will be described, with reference to the accompanying drawings.

### First Embodiment

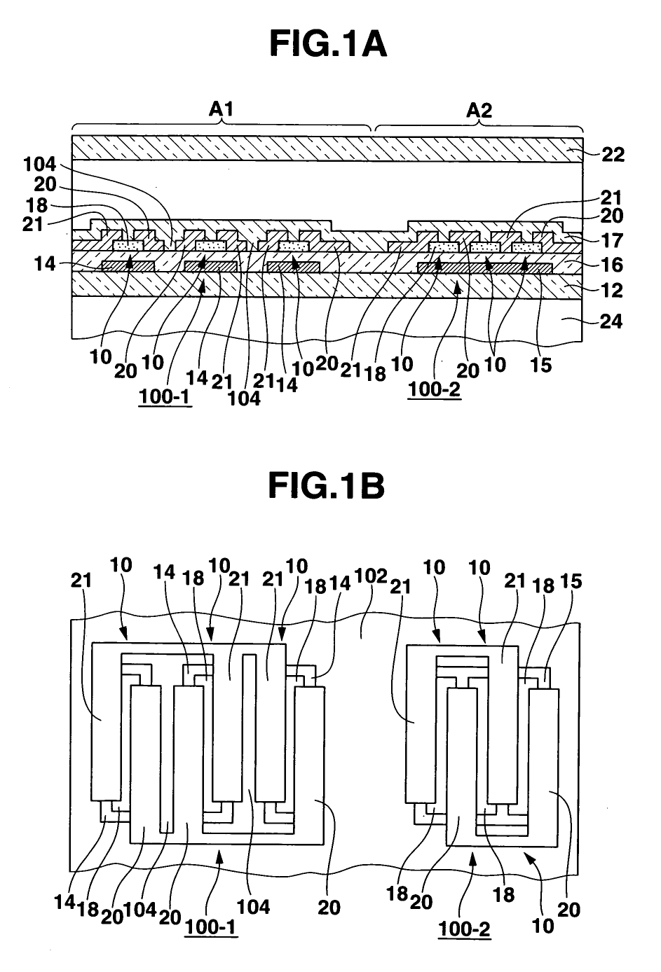

FIGS. 1A and 1B are a sectional view and a plan view, respectively, showing a photoelectric transducer according to the first embodiment of the present invention.

The photoelectric transducer has two regions A1 and A2. In the first region A1, a first sensor TFT 100-1, i.e., first photoelectric transducer element, is arranged. Similarly, in the second region A2, a second sensor TFT 100-2, i.e., second photoelectric transducer element, is arranged. The first regions A1 and second regions A2 are alternately arranged in rows and columns, spaced one form another by an inter-sensor region 102. Thus, the first sensor TFTs 100-1 and the second sensor TFTs 100-2 constitute a photoelectric-transducer element array. In FIGS. 1A and 1B, only one first region A1 and only one second region A2 are shown, and the components identical to those of the conventional TFT photoelectric transducer shown in FIG. 9 are designated by the same reference numbers.

The first sensor TFT 100-1 includes three TFT photoelectric elements 10. Each TFT photoelectric element 10 of the first sensor TFT 100-1 comprises a gate electrode (first light-shielding layer) 14 formed on a TFT substrate 12, a transparent insulating film 16 formed on the gate electrode 14, a photoelectric transducer part 18, which is made of a-Si, formed on the insulating film 16 and opposed to the gate electrode 14, and a source electrode 20 and a drain electrode 21, both formed on the photoelectric transducer part 18. The second sensor TFT 100-2 includes three TFT photoelectric elements 10, too. It differs in structure from the first sensor TFTs 100-1, only in that one gate electrode (second light-shielding layer) 15 is used in place of the three gate electrode 14. A transparent insulating film 17 covers the upper surfaces of the sensor TFTs 100-1 and 100-2. A transparent countersubstrate (mount layer) 22 is provided above the insulating film 17 spaced apart by a prescribed distance from the insulating film 17 by means of a seal member (not shown) or a gap member (not shown). The photoelectric transducer shown in FIG. 1A is thus fabricated.

In first sensor TFT 100-1 provided in the first region A1, the three TFT photoelectric transducer elements 10 are arranged adjacent to, spaced apart from, one another. Thus, three gate electrodes 14 are arranged in one plane, spaced apart from one another, and the three photoelectric transducer parts 18 are provided on these gate electrodes 14. The gate electrodes 14 are made of light-shielding material such as chromium, molybdenum, aluminum or tantalum. The gate electrodes 14 are connected to one another by a gate line (not shown). On each of the three photoelectric transducer parts 18, a source electrode 20 and a drain electrode 21, each composed of one or more layers of light-shielding material such as chromium, molybdenum, aluminum or tantalum, are arranged. In the first sensor TFT 100-1 provided in the first region A1 shown in FIG. 1A and composed of three TFT transducer elements 10, the source electrode 20 of the TFT transducer element 10 located on the right, the source electrode 20 of the TFT transducer element 10 located in the middle, and the source electrode 20 of the TFT transducer element 10 located on the left are connected to one another, forming the source electrode of the first sensor TFT 100-1. Further, the drain electrode 21 of the TFT transducer element 10 located on the right, the drain electrode 21 of the TFT transducer element 10 located in the middle, and the drain electrode 21 of the TFT transducer element 10 located on the left are connected to one another, forming the drain electrode of the first sensor TFT 100-1. The source electrodes 20 and the drain electrodes 21 are connected outside the region of the TFT transducer elements 10, so that slits (light-transmitting parts) 104 are made between the TFT transducer elements 10. Through these slits 104, light 26 emitted from a backlight (light-applying member) 24 can travel. The regions where the gate electrodes 14 are not formed) and the slits 104 between the source electrodes 20 and drain electrodes 21 serve as light-transmitting regions. The light 26 can emerge through the light-transmitting regions, after travelling from the backlight 24 (i.e., light-emitting means) provided on the lower surface of the TFT substrate 12. The backlight 24 may emit white light, red light or infrared rays.

In the second sensor TFT 100-2 provided in the second region A2, the three TFT photoelectric transducer elements 10 are arranged, not spaced apart from one another. That is, one gate electrode 15 (second light-shielding layer) is arranged in one plane, and the three photoelectric transducer parts 18 are provided on the gate electrode 15. A source electrode 20 and a drain electrode 21 are arranged on each photoelectric transducer part 18. In the second sensor TFT 100-2 provided in the second region A2 and composed of three TFT transducer elements 10, the source electrode 20 of the TFT transducer element 10 located on the right, the source electrode 20 of the TFT transducer element 10 located in the middle, and the source electrode 20 of the TFT transducer element 10 located on the left are connected to one another as in the first sensor TFT 100-1, forming the source electrode of the second sensor TFT 100-2. Further, the drain electrode 21 of the TFT transducer element 10 located on the right, the drain electrode 21 of the TFT transducer element 10 located in the middle, and the drain electrode 21 of the TFT transducer element 10 located on the left are connected to one another, forming the drain electrode of the second sensor TFT 100-2. Slits are not made between the TFT transducer elements 10 as in the first sensor TFT 100-1. In other words, the TFT transducer elements 10 contact one another, forming a continuous layer.

Since the second sensor TFT 100-2 does not have slits as the first sensor TFT 100-1 does, the part corresponding to the gate electrode 15 is a non-transmitting region. The non-transmitting region intercepts the light 26 emitted from the backlight 24 provided on the lower surface of the TFT substrate 12.

The above-mentioned prescribed distance to the countersubstrate 22 is determined by the gap between the TFT transducer elements 10 provided in the sensor TFT 100-1 and the refractive indices of the other components of the photoelectric transducer. That is, the prescribed distance is of such a value that the sensor TFT 100-1 performs accurate photoelectric conversion on the light 30 which is first applied from the backlight 24 arranged on the lower surface of the TFT substrate 12, which then travels to the countersubstrate 22 through the transmitting part of the first region A1 having the first sensor TFT 100-1, and which is finally reflected by an object, e.g., finger 28 resting on the countersubstrate 22. The TFT transducer elements 10 should preferably so designed that the light passing through the transmitting part of the second region A2 in which the second sensor TFT 100-2 is provided is 10 to 90% of the light passing through the transmitting region of the first sensor TFT 100-1. Note that the gap between the transparent countersubstrate 22 and the sensor TFTs 100-1 and 100-2 may be filled with air. Alternatively, it may be filled with liquid crystal if the photoelectric transducer is designed for use in a liquid crystal display panel.

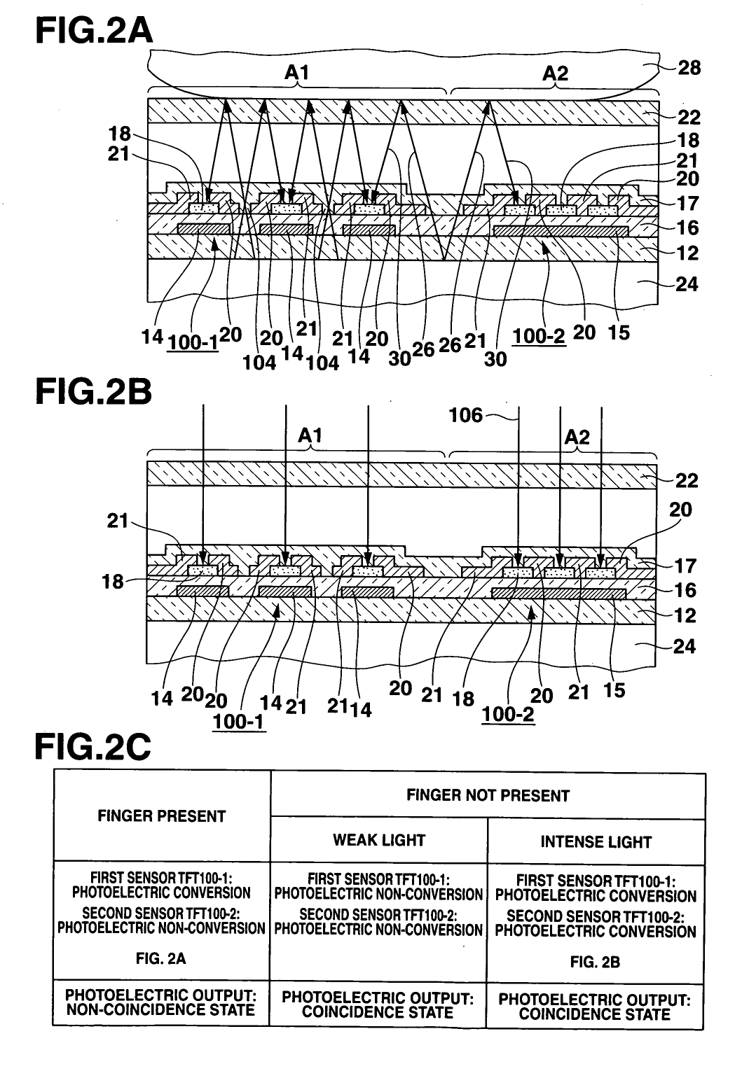

How the photoelectric transducer so configured as described above operates will be explained with reference to FIGS. 2A to 2C. FIG. 2A is a sectional view explaining how light travels when a finger 28 touches the countersubstrate 22. FIG. 2B is a sectional view explaining how intense extraneous light, if applied, travels. FIG. 2C is a table showing the various operating modes of the photoelectric transducer.

As shown in FIG. 2A, the light 26 emitted from the backlight 24 is applied from the inter-sensor regions 102 lying between the adjacent sensor TFT 100-1 and 100-2 and slits 104 of the sensor TFT 100-1 to the transparent countersubstrate 22 through the transparent TFT substrate 12, transparent insulating film 16 and transparent insulating film 17. The light 26 then emerges from the photoelectric transducer. The light 26 is reflected by the finger 28 (more precisely, the ridges defining the fingerprint, which are not shown) resting on the countersubstrate 22. The light 26 thus reflected is applied, as reflected light 30, back into the photoelectric transducer. In the photoelectric transducer, the reflected light 30 passes through the countersubstrate 22 and is then applied to the sensor TFTs 100-1 and 100-2.

In this case, regarding the first sensor TFT 100-1, the light 26 emitted from the backlight 24 is applied not only from the inter-sensor regions 102, but also from the regions of the slits 104. The reflected light 30 therefore includes the light 26 applied from the regions of the slits 104, too. The reflected light 30 is applied to the photoelectric transducer parts 18 of all three TFT transducer elements 10 that constitute the first sensor TFT 100-1. Hence, the first sensor TFT 100-1 is in a photoelectric conversion state.

In the second sensor TFT 100-2, the reflected light 30 consists of only the light 26 emitted from the backlight 24, applied from the inter-sensor regions 102 and reflected by the finger 28, because slits 104 are not made as the first sensor TFT 100-1. Hence, weak reflected light 30 is applied to the photoelectric transducer parts 18 of only the right and left TFT transducer elements 10. As a result, the second sensor TFT 100-2 is in a photoelectric nin-conversion state.

Hence, as long as the finger 28 touches the photoelectric transducer, the first sensor TFT 100-1 is the photoelectric conversion state, while the second sensor TFT 100-2 is the photoelectric non-conversion state, as shown in the left column of FIG. 2C. This state shall be called non-coincidence state of photoelectric-output (i.e., object-presence state).

Assume that the finger 26 does not touch the transparent countersubstrate 22 as shown in FIG. 2B and that extraneous light 106 having higher luminance than the light 26 emitted by the backlight 24, such as sunlight, is applied to the photoelectric transducer. Then, the extraneous light 106 passes through the countersubstrate 22 and is applied to both the first sensor TFT 100-1 and the second sensor TFT 100-2. Thus, the extraneous light 106 is applied to the photoelectric transducer parts 18 of all three TFT transducer elements 10 that constitute the first sensor TFT 100-1 and also to the photoelectric transducer parts 18 of all three TFT transducer elements 10 that constitute the second sensor TFT 100-2. As a result, both sensor TFTs 100-1 and 100-2 are in the photoelectric conversion state if no finger is resting and if light is intense as shown in the right column of the table in FIG. 2C. In the present embodiment, this state is defined as coincidence state of photoelectric-output (i.e., object-absence state).

Assume that the finger 26 does not touch the transparent countersubstrate 22 as shown in FIG. 2B and that extraneous light 106 having low luminance is applied to the photoelectric transducer. In this case, neither the first sensor TFT 100-1 nor the second sensor TFT 100-2 is in the photoelectric non-conversion state if no finger is resting and if light is weak as shown in the right column of the table in FIG. 2C. In the present embodiment, this state is defined as photometric-output coincidence state (i.e., object-absence state).

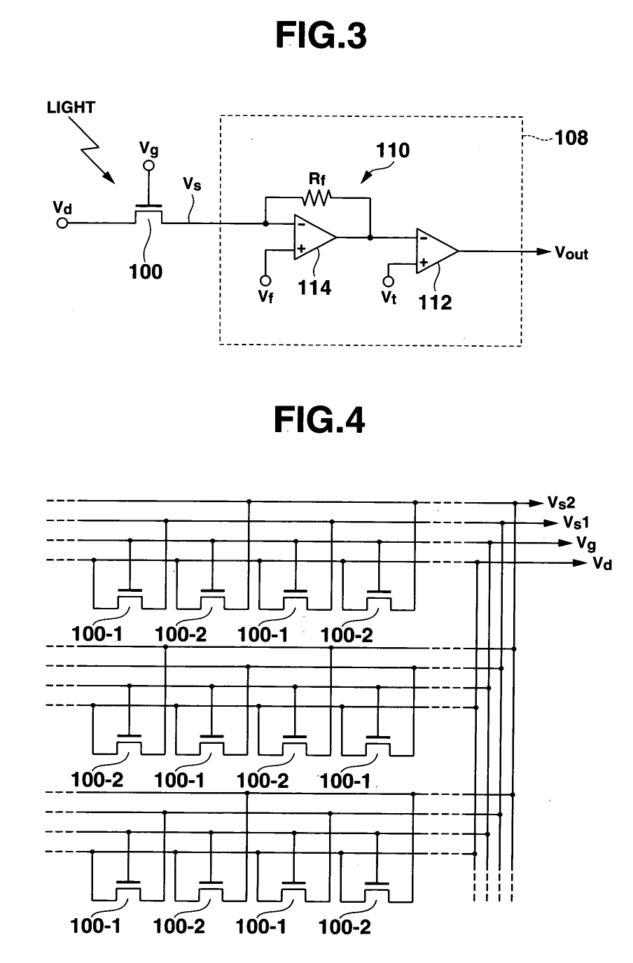

FIG. 3 is a circuit diagram of the detection circuit that determines whether the sensor TFTs 100-1 and 100-2 are in the photoelectric conversion state or the photoelectric non-conversion state. FIG. 4 is a diagram showing how the sensor TFTs 100-1 and 100-2 are electrically connected in the photoelectric transducer according to the first embodiment.

Whether the outputs of the sensor TFT 100-1 and 100-2 are not coincident or coincident can be determined by discriminating means that includes, for example, detection circuits of the type shown in FIG. 3.

As FIG. 3 shows, the detection circuit 108 comprises a current-to-voltage conversion circuit 110 and a comparator 112. The current-to-voltage conversion circuit 110 is composed of an inverting amplifier 114 and a feedback resistor Rf. The current-to-voltage conversion circuit 110 has its non-inverting input terminal applied with a preset voltage Vf. The feedback resistor Rf is connected between the output terminal and inverting input terminal of the inverting amplifier 114. The inverting input terminal of the inverting amplifier 114 is connected by a line to either the first sensor TFT 100-1 or the second sensor TFT 100-2 which is shown as a sensor TFT 100 in FIG. 3. The comparator 112 compares the voltage generated by the current-to-voltage conversion circuit 110 with a preset threshold voltage Vt, generating an output signal Vout that indicates whether the sensor TFT 100 is in the photoelectric conversion state or the photoelectric non-conversion state. The preset threshold voltage Vt is of such a value as to serve to detect reliably the photoelectric non-conversion state achieved by weak reflected light 30 applied to the second sensor TFT 100-2, i.e., light 26 applied from the inter-sensor regions 102 and reflected by the finger 28.

Although not shown in the drawings, the discriminating means has two detection circuits 108 of the type shown in FIG. 3, one for the first sensor TFT 100-1 and the other for the second sensor TFT 100-2. The discriminating means further has a discriminating circuit having a logic circuit (not shown) for performing a logic operation on the output signals Vout of the two detection circuits 108. The discriminating means can therefore determines the non-coincidence state, if the output signals Vout of the first and second sensor TFTs 100-1 and 100-2 are “1” and “0,” respectively.

The two detection circuits to which the first and second sensor TFTs 100-1 and 100-2 are connected, respectively, may be connected to the discriminating circuit that includes a non-coincidence circuit. Then, if the discriminating circuit outputs “1,” the photoelectric outputs represent the non-coincidence state, showing that the finger 28 rests on the photoelectric transducer. If the discriminating circuit outputs “0,” the photoelectric output represent the coincidence state, showing that the finger 28 does no rest on the photoelectric transducer.

The operating principle specified above can provide a mechanism that recognizes non-coincidence state (i.e., object-presence state) in the case where the finger 28 touches the photoelectric transducer, and recognizes coincidence state (i.e., object-absence state) in any other case.

In practice, the photoelectric transducer has a plurality of sensor TFTs arranged in rows and columns, providing a two-dimensional array such that the first sensor TFTs and the second sensor TFTs are alternately arranged. Gate electrodes 14 and 15, source electrodes 20, drain electrodes 21 and lines are so formed and arranged, connecting the first sensor TFTs 100-1 in parallel, and connecting the second sensor TFTs 100-2 in parallel. This eliminates the difference in photoelectric condition between any first sensor TFT 100-1 and any second sensor TFT 100-2, said difference resulting from the locations of the sensor TFTs 100-1 and TFT 100-2.

As FIG. 4 shows, the gate electrode 14 of each first sensor TFT 100-1 is connected to a gate line Vg, the drain electrode of the first sensor TFT 100-1 is connected to a drain line Vd, and the source electrode of the first sensor TFT 100-1 is connected to a first source line Vs1. Similarly, the gate electrode 15 of each second sensor TFT 100-2 is connected to the same gate line Vg as is the gate electrode 14 of the first sensor TFT 100-1, the drain electrode of the second sensor TFT 100-2 is connected to the same drain line Vd as is the drain electrode of the first sensor TFT 100-1, and the source electrode of the second sensor TFT 100-2 is connected to a second source line Vs2, not to the first source line Vs1 to which the drain electrode of the first sensor TFT 100-1 is connected.

Connected to the various lines in this manner, the first sensor TFTs 100-1 constitute a first sensor TFT unit, while the second sensor TFTs 100-2 constitute a first sensor TFT unit. The source lines Vs1 and Vs2 connected to the first and second sensor TFT units, respectively, are connected to the two detection circuits 108 of the same configuration, respectively. Therefore, the first detection circuit 108 can determine whether the first sensor TFT unit is in a photoelectric conversion state or a photoelectric non-conversion state, and the second detection circuit 108 can determine whether second sensor TFT unit is in a photoelectric conversion state or a photoelectric non-conversion state. Thus, in the photoelectric transducer, the first sensor TFTs 100-1 and the second sensor TFTs 100-2 are arranged adjacent to one another, the first sensor TFTs 100-1 are connected in parallel, and the second sensor TFTs 100-2 are connected in parallel. From the synthesized output of the first sensor TFTs 100-1 and the synthesized output of the second sensor TFTs 100-2, the detection circuits 108 detect the photoelectric conversion state/photoelectric non-conversion state, and the discriminating circuit can accurately determine whether the photoelectric transducer assumes the coincidence state or the non-coincidence state.

As described above, the first sensor TFT 100-1 allows the passage of the light 26 emitted from the backlight 24 and the second sensor TFT 100-1 does not allow the passage of the light 26 in the photoelectric transducer according to present embodiment. Therefore, the reflected light 30 is much applied to the first sensor TFT 100-1 and scarcely input to the second sensor TFT 100-2. Hence, if reflected light 30 exists in the photoelectric transducer, a difference develops between the outputs of the first sensor TFT 100-1 and the output of the second sensor TFT 100-2. If reflected light 30 does not exist, no difference develops between the outputs of the sensor TFTs 100-1 and TFT 100-2.

The first sensor TFTs 100-1 and the second sensor TFTs 100-2 are arranged adjacent, forming a transducer-elements array. The outputs of the transducer-elements array are supplied to the discriminating means that comprises the detection circuits 108 and the discriminating circuit. Thus, in the photoelectric transducer, the detection circuits 108 and the discriminating circuit cooperate to determine whether an object lies on the photoelectric transducer as described above.

The present embodiment is therefore advantageous in that whether a finger 28 rests on the photoelectric transducer can be determined, no matter whether the extraneous light has luminance equal to or higher than the light 26 emitted from the backlight. The first sensor TFT 100-1 allows, to some extent, the passage of the light 26 emitted from the backlight 24 (e.g., the first sensor TFT 100-1 has a light-transmittance of 5 to 95%). On the other hand, the second sensor TFT 100-2 does not allow the passage of the light 26 emitted from the backlight 24 (e.g., the second sensor TFT 100-2 has a light-transmittance of 0%). Nonetheless, the second sensor TFT 100-2 may have slits 104 to allow the passage of the light 26 to some extent, as the first sensor TFT 100-1 does. In this case, the first and second sensor TFTs 100-1 and 100-2 should have different light-transmittances so that the outputs the detection circuits 108 generate from the two reflected light beams 30 passing through the first and second sensor TFTs 100-1 and 100-2, respectively, may be well distinguished in spite of the performance difference between the detection circuits 108.

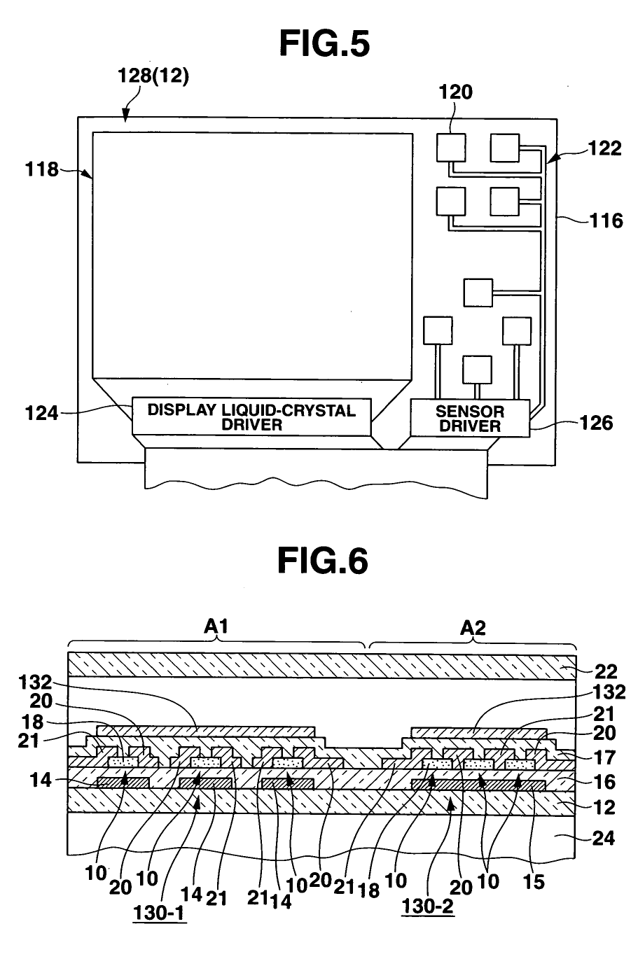

FIG. 5 is a plan view of a liquid crystal display panel 116 that incorporates a plurality of photoelectric transducers according to the first embodiment.

The display panel 116 has a display region 118 and a touch-panel region 122 which is composed of a plurality of touch sensors 120. To the display region 118, a display liquid-crystal driver 124 is connected. The display liquid-crystal driver 124 comprises thin-film transistors. The touch sensors 120 in the touch-panel region 122 are connected to a sensor driver 126. In the display region 118, pixel TFTs (switching elements) and pixel electrodes are arranged, forming a matrix pattern, each pixel electrode being connected to one pixel TFT. The pixel TFTs are identical in structure to the sensor TFTs 100-1 and 100-2, except that their tops are covered with a light-shielding film. Each touch sensor 120 includes at least one first region A1 and one second region A2, in which a first sensor TFT 100-1 and a second sensor TFT 100-2 are arranged, respectively. The touch sensors 120 have the same structure as shown in FIG. 1. The sensor driver 126 functions as discriminating means that includes the detection circuits 180 described above. The pixel TFTs, the display liquid-crystal driver 124, the sensor TFTs 100-1 and 100-2 and the sensor driver 126 can be formed in the same manufacturing step, on a TFT substrate 128 that is made of glass or plastics. If this is the case, the TFT substrate 12 of the photoelectric transducer corresponds to the TFT substrate 128 of the touch-panel region 122. The countersubstrate 22 and the backlight 24 are provided for both the display region 118 and the touch-panel region 122.

In the embodiment described above, the display liquid-crystal driver 124 and the sensor driver 126 may be constituted by LSI chips.

In the photoelectric transducer and the display panel having the photoelectric transducer, both according to the first embodiment of this invention, the first regions A1 each including the first sensor TFT 100-1 used as a first photoelectric transducer element are arranged adjacent to the second regions A2 each including the second sensor TFT 100-2 used as a second photoelectric transducer element to compose a photoelectric-transducer element array. The light 26 emitted from the backlight 24 passes through the transmitting part of each first region A1 in which the first sensor TFT 100-1 is arranged, in a greater amount than the light 26 that passes through the transmitting part of each second region A2 in which the second sensor TFT 100-2 is arranged. Each first sensor TFT 100-1 performs photoelectric conversion on the reflected light 30, i.e., light reflected by the finger 28 that is an object to detect. Both the first sensor TFT 100-1 and the second sensor TFT 100-2 perform photoelectric conversion on extraneous light, such as sunlight. The sensors TFT 100-1 and 100-2 can generate an output that accords with the type of the input light. Signal light, such as the reflected light, can therefore be distinguished from the extraneous light, such as sunlight.

The outputs of the sensor TFTs 100-1 and 100-2 are supplied to the discriminating means including the detection circuits 108. From the outputs of the detection circuits 108, it is determined whether an object that should be detected exists on the photoelectric transducer.

Since an object is reliably found to exist if only the first sensor TFT 100-1, for example, generates an output, an erroneous operation can be prevented. If both the first sensor TFT 100-1 and the second sensor TFT 100-2 generate an output, an object is found not to exist. In this case, the photoelectric transducer does not erroneously operate even if extraneous light is applied to it. If neither the first sensor TFT 100-1 nor the second sensor TFT 100-2 generates an output, an object is found not to exist. In other words, no objects are found to exist if neither reflected light nor extraneous light is applied to the sensor TFTs 100-1 and 100-2. In this case, too, no errors develop. Thus, the photoelectric transducer does not erroneously operate, in spite of the extraneous light 106 (mainly sunlight) it has received.

The photoelectric transducer according to this invention has the same structure as the liquid crystal display panel that constitutes the display region 118. Therefore, the photoelectric transducer can be integrally formed with the display panel, by using a TFT substrate common to it and the display panel. (That is, the display panel 116 having touch sensors 120 can be produced, scarcely increasing the number of manufacturing steps.) If this is the case, the backlight 24 can be the backlight that is provided in the display region 118.

### Second Embodiment

FIG. 6 is a sectional view showing the configuration of a photoelectric transducer according to the second embodiment of the present invention. The components of the photoelectric transducer according to this embodiment, which are identical to those of the photoelectric transducer according to the first embodiment, are designated by the same reference numbers and will not be described. For simplicity of illustration, only one pair of photoelectric transducer elements is shown in FIG. 6.

The photoelectric transducer according to the second embodiment differs from the first embodiment in that the photoelectric transducer elements are first and second double-gate (DG) TFT sensors 130-1 and 130-2, each constituted by a double-gate a-Si TFT, not first and second sensor TFTs 100-1 and 100-2 each of which is constituted by an a-Si TFT.

The first and second DG TFT sensors 130-1 and 130-2 are arranged in the first region A1 and the second region A2, respectively. The first and second DG TFT sensors 130-1 and 130-2 each comprise gate electrodes 14 or a gate electrode 15, a transparent insulating film 16, photoelectric transducer parts 18, source electrodes 20, drain electrodes 21, an insulating film 17, and a transparent upper gate electrode 132. The gate electrodes 14 are formed on a transparent TFT substrate 12 in the first DG TFT sensors 130-1. The gate electrode 15 is formed on a transparent TFT substrate 12 in the second DG TFT sensors 130-2. The transparent insulating film 16 is formed on the gate electrodes 14 or the gate electrode 15. The photoelectric transducer parts 18 are formed on the insulating film 16 and opposed to the gate electrodes 14 or the gate electrode 15. The source electrodes 20 and drain electrodes 21 are formed on the photoelectric transducer parts 18. The insulating film 17 covers the upper surfaces of the photoelectric transducer parts 18, source electrodes 20 and drain electrodes 21. The transparent upper gate electrode 132 is provided on the insulating film 17 and aligned with the photoelectric transducer parts 18, source electrodes 20 and drain electrodes 21.

Having DG TFT sensors 130-1 and 130-2 so configuration as described above, this photoelectric transducer achieves the same advantages as the first embodiment. Further, its sensitivity can be well controlled by operating the two gates at different times, to attain a great bright/dark output ratio.

### Third Embodiment

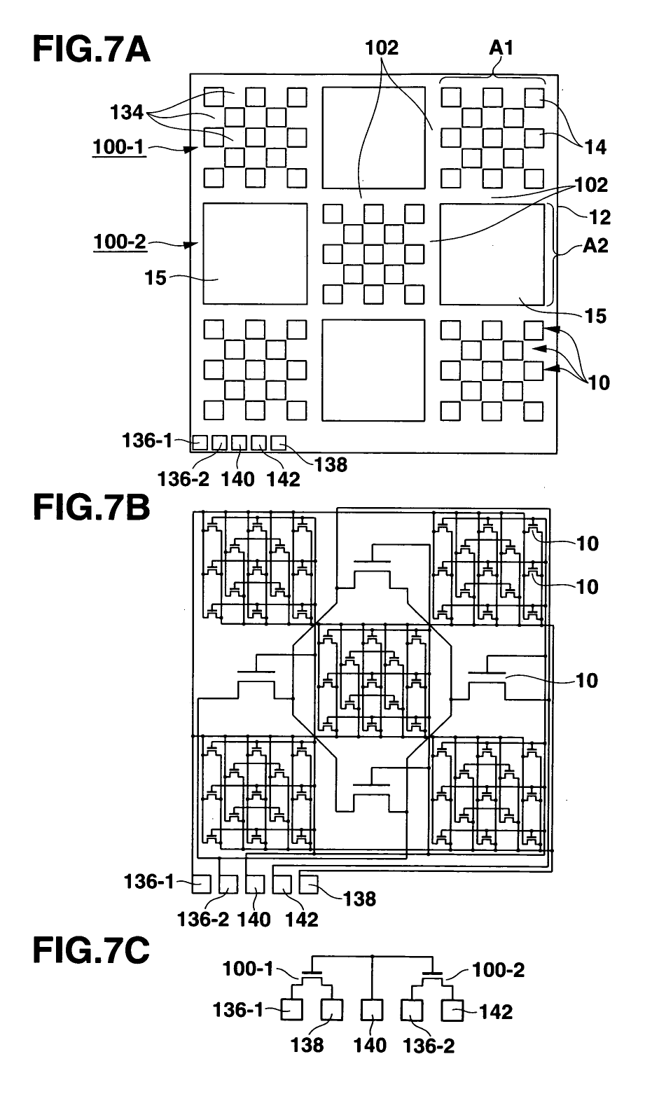

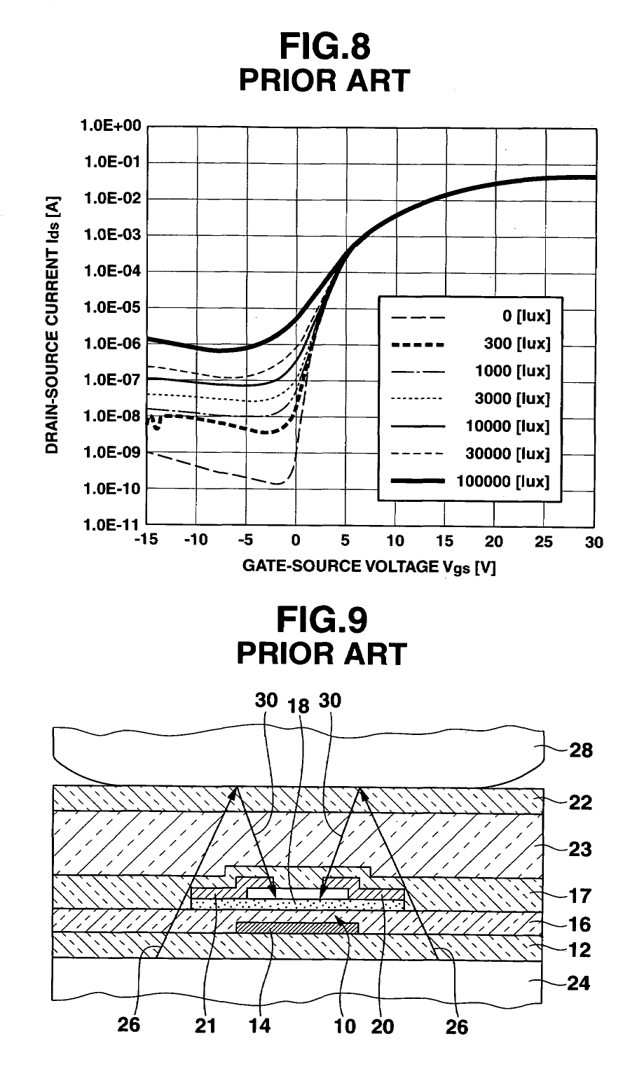

FIG. 7A is a plan view showing the configuration of a photoelectric transducer according to the third embodiment of the invention. This photoelectric transducer has five first regions A1 each including a first sensor TFT 100-1 and four second regions A2 each including a second TFT 100-2. For simplicity of illustration, only the gate electrodes 14 and the gate electrodes 15 are shown in FIG. 7A. FIG. 7B is a diagram representing the circuit configuration of the photoelectric transducer. FIG. 7C is an equivalent circuit diagram of the photoelectric transducer.

As shown in FIG. 7A, the first sensor TFT 100-1 arranged in each first region A1 comprises thirteen small TFT transducer elements 10. The TFT transducer elements 10 are arranged, forming a checkerboard pattern in the first region A1. On the other hand, the second sensor TFT 100-2 arranged in each second region A2 comprises one large TFT transducer element 10. The TFT transducer elements 10 constituting the first sensor TFT 100-1 and the TFT transducer element 10 constituting the second sensor TFT 100-2 have the same structure, though the elements 10 of the first sensor TFT 100-1 differ in size from the element 10 of the second sensor TFT 100-2. More precisely, any TFT transducer element 10 comprises a gate electrode 14 or 15, a transparent insulating film 16 formed on the gate electrode 14 or 15, a photoelectric transducer part 18 made of a-Si and formed on the gate electrode 14 or 15, a source electrode 20 formed on the photoelectric transducer part 18, and a drain electrode 21 formed on the photoelectric transducer part 18.

The TFT transducer elements 10 of the first sensor TFT 100-1 are arranged in a checkerboard pattern, defining inter-element regions 134 that arranged in rows and columns. The TFT transducer element 10 of the second sensor TFT 100-2 has a size equal to the sum of the sizes of the TFT transducer elements 10 and inter-element regions 134 of the first sensor TFT 100-1. For example, the gate electrodes 14 of each TFT transducer element 10 of the first sensor TFT 100-1 has a size of 0.5 mm×0.5 mm, while the gate electrode 15 of the TFT transducer element 10 of the second sensor TFT 100-2 has a size of 2 mm×2 mm.

As shown in FIG. 7B, the drain electrodes of all TFT transducer elements 10 of every first sensor TFT 100-1 are connected to a Vd terminal 136-1, the source electrodes thereof are connected to a Vs1 terminal 138, and the gate electrodes thereof are connected to a Vg terminal 140. Similarly, the drain electrode of the TFT transducer elements 10 of every second sensor TFT 100-2 is connected to a Vd terminal 136-2, the source electrode thereof is connected to the Vss terminal 142, and the gate electrode thereof is connected to the Vg terminal 140. Hence, the photoelectric transducer according to the third embodiment can be regarded as a circuit that comprises, as shown in FIG. 7C, one first sensor TFT 100-1 and one second sensor TFT 100-2.

In the photoelectric transducer so configured as shown in FIGS. 7A, 7B and 7C, the light 26 emitted from the backlight 24 is applied from the inter-sensor regions 102 lying between the adjacent sensor TFT 100-1 and 100-21 and from the inter-element regions 134 lying between the TFT transducer elements 10 of each first sensor TFT 100-1, passes through the transparent TFT substrate 12 and transparent insulating film 16, and is applied to the countersubstrate 22. The light 26 then emerges from the photoelectric transducer. The light 26 is reflected the finger 28 touching the countersubstrate 22. The light 26 thus reflected is applied, as reflected light 30, back into the photoelectric transducer. In the photoelectric transducer, the reflected light 30 passes through the countersubstrate 22 and is then applied to the sensor TFTs 100-1 and 100-2.

In the first sensor TFT 100-1, the light 26 emitted from the backlight 24 is applied not only from the inter-sensor regions 102, but also from the inter-element regions 134. Thus, the reflected light 30 includes the light 26 applied from the inter-element regions 134, too. Therefore, the reflected light 30 is applied to the photoelectric transducer parts 18 of all sixty-five TFT transducer elements 10 that constitute the first sensor TFT 100-1. Hence, the first sensor TFT 100-1 is in a photoelectric conversion state.

In the second sensor TFT 100-2 which does not have such inter-element regions 134 as the first sensor TFT 100-2 has, the reflected light 30 consists of only the light 26 applied from the inter-sensor regions 102 and reflected by the finger 28. Hence, only weak reflected light 30 is applied to the photoelectric transducer parts 18 of the four TFT transducer elements 10 that constitute the second sensor TFT 100-2. As a result, the second sensor TFT 100-2 is in a photoelectric non-conversion state.

Hence, as long as the finger 28 rests on the photoelectric transducer, the first sensor TFT 100-1 performs photoelectric conversion, while the second sensor TFT 100-2 does not perform photoelectric conversion.

Assume that the finger 26 does not touch the transparent countersubstrate 22 and that extraneous light 106 having higher luminance than the light 26 emitted by the backlight 24, such as sunlight, is applied to the photoelectric transducer. Then, the extraneous light 106 passes through the countersubstrate 22 and is applied to both the first sensor TFT 100-1 and the second sensor TFT 100-2. Thus, the extraneous light 106 is applied to the photoelectric transducer parts 18 of all sixty-five TFT transducer elements 10 that constitute the first sensor TFT 100-1 and also to the photoelectric transducer parts 18 of all four TFT transducer elements 10 that constitute the second sensor TFT 100-2. As a result, both sensor TFTs 100-1 and 100-2 perform photoelectric conversion.

Assume that the finger 26 does not touch the transparent countersubstrate 22 and that extraneous light 106 having low luminance is applied to the photoelectric transducer. In this case, neither the first sensor TFT 100-1 nor the second sensor TFT 100-2 performs photoelectric conversion.

Whether the finger 28 is touch or not to the transparent countersubstrate 22 can be determined from outputs of the first and second sensor TFTs 100-1 and 100-2 by discriminating means that includes, for example, two detection circuits 108 of the type explained in conjunction with the first embodiment and a logic circuit that performs logic operation on the output signals Vout of the detection circuits 108. That is, the Vs1 terminal 136 is connected to the inverting input terminal of the inverting amplifier 114 of one detection circuit 108, and the Vs2 terminal 138 is connected to the inverting input terminal of the inverting amplifier 114 of the other detection circuit 108.

In the photoelectric transducer according to the third embodiment of this invention, the first sensor TFT 100-1 as first transducer element is arranged adjacent to the second sensor TFT 100-2 as second transducer element. Each first sensor TFT 100-1 allows passage of more light than the second sensor TFT 100-2. Therefore, the first sensor TFT 100-1 performs photoelectric conversion on the reflected light 30, i.e., light reflected by the finger 28, and the first and second sensor TFTs 100-1 and 100-2 perform photoelectric conversion on the extraneous light such as sunlight. The sensors TFT 100-1 and 100-2 can generate an output that accords with the type of the input light. Signal light, such as the reflected light, can therefore be distinguished from the extraneous light, such as sunlight.

The display panel 116 described in conjunction with the first embodiment can be produced if photoelectric transducers of the type according to the third embodiment are incorporated as touch sensors 120 in a liquid crystal display panel.

The above-specified size of the TFT transducer elements 10 constituting the first sensor TFT 100-1, and the above-specified size of the TFT transducer elements 10 constituting the second sensor TFT 100-2 are no more than exemplified values. The TFT transducer elements 10 may have any size that serves to prevent the reflected light 30 that the first sensor TFT 100-1 detects (i.e., light 26 applied from the inter-element regions 134) from leaking to the adjacent second sensor TFT 100-2 through the countersubstrate 22. Note that the countersubstrate 22 is very thick (about 1 mm at most), while the distance between the sensor TFTs 100-1 and 100-2, on the one hand, and the countersubstrate 22, on the other, is only a few microns (μm). Inevitably, the countersubstrate 22 is the main light-leakage path. If the TFT transducer elements 10 constituting the first sensor TFT 100-1 are much longer than that distance, they will prevent the reflected light from leaking to the second sensor TFT 100-2.

In the third embodiment, too, the first and second sensor TFTs 100-1 and 100-2 may of course be replaced by first and second DG TFT sensors 130-1 and 130-2, each constituted by a double-gate a-Si TFT used as TFT transducer element 10.

The present invention has been described, with reference to several embodiments. This invention is not limited to the embodiments, nevertheless. Various changes and modifications can, of course, be made within the scope and spirit of the present invention.

For example, the gate electrodes 14 provided in the first sensor TFT 100-1 and the gate electrode 15 provided in the second sensor TFT 100-2 are used as light-shielding layers, as well, for shielding the light 26 emitted by the backlight 24. Instead, the gate electrodes 14 and the gate electrode 15 may be made of transparent material, and light-shielding layers made of light-shielding material may be interposed between the gate electrodes 14 and the gate electrode 15, on the one hand, and the back light 24, on the other.

In the first sensor TFT 100-1, the gate electrodes 14 are arranged below the photoelectric transducer parts 18 and the source electrodes 20 and drain electrodes 21 are arranged above the photoelectric transducer parts 18. In the second sensor TFT 100-2, the gate electrode 15 is arranged below the photoelectric transducer parts 18 and the source electrodes 20 and drain electrodes 21 are arranged above the photoelectric transducer parts 18. The first and second sensor TFT 100-1 and TFT 100-2 are therefore of an inverted stagger type. Instead, they may be of a coplanar type in which the gate electrodes 14 or gate electrode 15 is arranged above the photoelectric transducer parts 18, like the source electrodes 20 and drain electrodes 21. Alternatively, they may be an erected stagger type or an inverted coplanar type.

In the second embodiment, the sensor TFTs 100-1 and 100-2 used as photoelectric transducer elements are each constituted by a double-gate a-Si TFT. Instead, they may be multi-gate a-Si TFTs, each having more gate electrodes than the double-gate a-Si TFT.

In the first to third embodiments, the photoelectric transducer elements are amorphous silicon TFTs. The photoelectric transducer elements may be of any other type, such as polysilicon TFTs. Further, they are not limited to transistors (e.g., TFTs). For example, photoelectric transducer elements of any other type, such as photodiodes, can be used.

The photoelectric transducers according to the first to third embodiments have photoelectric transducer elements of one type (first sensor TFTs 100-1 or first DG-type TFTs) and photoelectric transducer elements of another type (second sensor TFTs 100-1 or second DG-type TFTs). Nevertheless, the present invention can provide a photoelectric transducer that has photoelectric transducer elements of three or more types.

Furthermore, the detection circuits 108 are not limited to the one having the configuration shown in FIG. 3. For example, a buffer amplifier (i.e., voltage follower) may be connected between the output of the inverting amplifier 114 and the input of the comparator 112.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A photoelectric transducer comprising:
a photoelectric-transducer element array which has a first region in which a first photoelectric transducer element having a photoelectric transducer part is arranged and a second region in which a second photoelectric transducer element having photoelectric transducer part is arranged;
a light-emitting member which is arranged below the photoelectric-transducer element array and which emits light to the photoelectric-transducer element array;
a mount layer which is arranged above photoelectric-transducer element array and on which an object is to rest to reflect the light emitted from the light-emitting member toward the photoelectric-transducer element array, to the first photoelectric transducer element and the second photoelectric transducer element;
a first light-shielding layer which is provided between the light-emitting member and the photoelectric transducer part of the first photoelectric transducer element; and
a second light-shielding layer which is provided between the light-emitting member and the photoelectric transducer part of the second photoelectric transducer element and having a larger area than the first light-shielding layer,
wherein the light emitted from the light-emitting member toward the photoelectric-transducer element array passes through the first region in a larger amount than through the second region.

2. The photoelectric transducer according to claim 1, wherein the first and second photoelectric transducer elements have a thin-film-transistor photoelectric transducer element which has a gate electrode, a source and a drain electrodes, the first light-shielding layer is the gate electrode of the first photoelectric transducer element, and the second light-shielding layer is the gate electrode of the second photoelectric transducer element.

3. The photoelectric transducer according to claim 2, wherein the first photoelectric transducer element has a plurality of thin-film-transistor transducer elements, each having a gate electrode which is spaced apart from that of any adjacent one, defining a separating region.

4. The photoelectric transducer according to claim 3, wherein in the first photoelectric transducer element, each of thin-film-transistor transducer elements further has a source electrode connected to adjacent one, a drain electrode connected to adjacent one, and each of the source electrode and the drain electrode has a light-transmitting part located above the separating region between the gate electrodes.

5. The photoelectric transducer according to claim 4, wherein the light-transmitting part is a slit provided between the gate electrodes.

6. The photoelectric transducer according to claim 3, wherein the first region and the second region have the same area, and more thin-film-transistor transducer elements are provided in the first region than in the second region.

7. The photoelectric transducer according to claim 1, further comprising discriminating means including detection circuits which detect an output of the first photoelectric transducer element and an output of the second photoelectric transducer element, respectively.

8. The photoelectric transducer according to claim 7, wherein the photoelectric-transducer element array comprises a plurality of first photoelectric transducer element arranged in the first region and a plurality of second photoelectric transducer element arranged in the second region, and each detection circuit has an input terminal which receives at least one of (I) the outputs of said plurality of first photoelectric transducer element and (II) the outputs of said plurality of second photoelectric transducer element.

9. The photoelectric transducer according to claim 7, wherein the discriminating means determines whether the object rests on the mount layer, on the basis of the output of the first photoelectric transducer element and the output of the second photoelectric transducer element.

10. The photoelectric transducer according to claim 7, wherein the discriminating means determines that the object rests on the mount layer, when the output of the first photoelectric transducer element and the output of the second photoelectric transducer element do not coincide with each other.

11. The photoelectric transducer according to claim 1, wherein the first photoelectric transducer element comprises a plurality of thin-film-transistor transducer elements, the second photoelectric transducer element comprises a fewer thin-film-transistor transducer elements than the first photoelectric transducer element, a plurality of first regions are provided, in each of which a first photoelectric transducer element is arranged, and a plurality of second regions are provided, in each of which a second photoelectric transducer element is arranged.

12. The photoelectric transducer according to claim 11, wherein the first regions and the second regions are alternately arranged.

13. The photoelectric transducer according to claim 12, wherein the thin-film-transistor transducer elements are amorphous silicon thin-film transistors.

14. The photoelectric transducer according to claim 13, wherein the thin-film-transistor transducer elements are double-gate amorphous silicon thin-film transistors.

15. A photoelectric transducer comprising:
a first region in which a plurality of first photoelectric transducer elements are arranged, each having a plurality of thin-film-transistor transducer elements;
a second region in which a plurality of second photoelectric transducer elements are arranged, each having at least one thin-film-transistor transducer element;
a light-emitting member which emits light to the first region and the second region;
a first light-shielding layer which is provided between the first region and the light-emitting member;
a second light-shielding layer which is provided between the second region and the light-emitting member and which has a larger area than the first light-shielding layer;
a mount layer on which an object is to rest to reflect the light emitted from the light-emitting member toward the first region and the second region;
a discriminating circuit which is connected to a first source line Vs1 connecting the source electrodes of the thin-film-transistor transducer elements of the first photoelectric transducer elements and to a second source line Vs2 connecting the source electrodes of the at least one thin-film-transistor transducer element of the second photoelectric transducer elements and which is configured to determine whether the object rests on the mount layer, on the basis of a signal input through the first source line Vs1 and a signal input through the second source line Vs2.

16. The photoelectric transducer according to claim 15, wherein the first region and the second region are substantially identical in size.

17. The photoelectric transducer according to claim 15, wherein the photoelectric transducer includes a plurality of the first region and a plurality of the second region, and the first regions and the second regions are arranged in a matrix pattern.

18. The photoelectric transducer according to claim 17, wherein the first region and the second region are alternately arranged.

19. The photoelectric transducer according to claim 15, wherein each of the second photoelectric transducer element formed in the second region has one thin-film-transistor transducer element.

20. The photoelectric transducer according to claim 19, wherein the second light-shielding layer is the gate electrode of the thin-film-transistor transducer element and has a size substantially equal to the size of the second region.

21. A photoelectric transducer comprising:
a photoelectric-transducer element array which has a first region in which a first photoelectric transducer element having a photoelectric transducer part is arranged and a second region in which a second photoelectric transducer element having photoelectric transducer part is arranged;
a light-emitting member which is arranged below the photoelectric-transducer element array and which emits light to the photoelectric-transducer element array;
a countersubstrate which is arranged above photoelectric-transducer element array and on which an object is to rest to reflect the light emitted from the light-emitting member toward the photoelectric-transducer element array, to the first photoelectric transducer element and the second photoelectric transducer element;
a first light-shielding layer which is provided between the light-emitting member and the photoelectric transducer part of the first photoelectric transducer element;
a second light-shielding layer which is provided between the light-emitting member and the photoelectric transducer part of the second photoelectric transducer element and having a larger area than the first light-shielding layer; and
a liquid crystal which is arranged between the countersubstrate and the photoelectric transducer element array,
wherein the light emitted from the light-emitting member toward the photoelectric-transducer element array passes through the first region in a larger amount than through the second region.

22. A display panel having a display region and a touch-panel region and comprising:
a TFT substrate;
a light-emitting member which is arranged on a lower surface of the TFT substrate;
a countersubstrate which is spaced apart from and opposed to an upper surface of the TFT substrate, wherein between the countersubstrate and that part of the TFT substrate which is aligned with the display region, there are provided:
pixel electrodes;
switching elements which are connected to the pixel electrodes; and
a liquid crystal which covers the switching elements, and
wherein between the countersubstrate and that part of the TFT substrate which is aligned with the touch-panel region, there are provided:
a photoelectric-transducer element array which has a first region in which a first photoelectric transducer element having a photoelectric transducer part is arranged and a second region in which a second photoelectric transducer element having a photoelectric transducer part is arranged;
a light-emitting member which is arranged below the photoelectric-transducer element array and which emits light to the photoelectric-transducer element array;
a mount layer which is arranged above photoelectric-transducer element array and on which an object is to rest to reflect the light emitted from the light-emitting member toward the photoelectric-transducer element array, to the first photoelectric transducer element and the second photoelectric transducer element;
a first light-shielding layer which is provided between the light-emitting member and the photoelectric transducer part of the first photoelectric transducer element; and
a second light-shielding layer which is provided between the light-emitting member and the photoelectric transducer part of the second photoelectric transducer element and having a larger area than the first light-shielding layer.

23. The display panel according to claim 22, wherein the first and second photoelectric transducer elements have a thin-film-transistor photoelectric transducer element which has a gate electrode, a source and a drain electrode, the first light-shielding layer is the gate electrode of the first photoelectric transducer element, and the second light-shielding layer is the gate electrode of the second photoelectric transducer element.

24. The display panel according to claim 23, wherein the first photoelectric transducer element has a plurality of thin-film-transistor transducer elements, each having a gate electrode which is spaced apart from that of any adjacent one, defining a separating region.

25. The display panel according to claim 24, wherein in the first photoelectric transducer element, the source electrodes of the thin-film-transistor transducer elements are connected to one another, the drain electrodes thereof are connected to one another, and slits are provided above regions between the gate electrodes.

26. The display panel according to claim 24, wherein the first region and the second region have the same area, and more thin-film-transistor transducer elements are provided in the first region than in the second region.

27. The display panel according to claim 22, further comprising discriminating means including detection circuits which detect an output of the first photoelectric transducer element and an output of the second photoelectric transducer element, respectively.

28. The display panel according to claim 27, wherein the photoelectric-transducer element array comprises a plurality of first photoelectric transducer element arranged in the first region and a plurality of second photoelectric transducer element arranged in the second region, and the each detection circuit has each an input terminal which receives one of (I) the outputs of said plurality of first photoelectric transducer element and (II) the outputs of said plurality of second photoelectric transducer element.

29. The display panel according to claim 27, wherein the discriminating means determines whether the object rests on the mount layer, on the basis of the output of the first photoelectric transducer element and the output of the second photoelectric transducer element.
